(19) United States
(12) Patent Application Publication
(10) Pub. No.: US 2021/0226045 A1
(43) Pub. Date: Jul. 22, 2021

(54) HETEROJUNCTION BIPOLAR TRANSISTOR

(71) Applicant: VISUAL PHOTONICS EPITAXY CO., LTD., Taoyuan City (TW)

(72) Inventors: Chao-Hsing Huang, Taoyuan City (TW); Yu-Chung Chin, Taoyuan City (TW); Min-Nan Tseng, Taoyuan City (TW); Kai-Yu Chen, Taoyuan City (TW)

(21) Appl. No.: 17/155,286

(22) Filed: Jan. 22, 2021

(30) Foreign Application Priority Data
Jan. 22, 2020 (TW) 109102671

(51) Int. Cl. H01L 29/737; H01L 29/205

(52) U.S. Cl. CPC H01L 29/7371; H01L 29/2003; H01L 29/205

(57) ABSTRACT

Provided is a heterojunction bipolar transistor (HBT), including a collector layer. The collector layer includes a bandgap graded. A quasi-electric field generated by the bandgap graded will enable electrons in the bandgap graded layer to be accelerated.

### CROSS-REFERENCE TO RELATED APPLICATION

This application claims priority to Taiwanese Application Serial No. 109102671, filed on Jan. 22, 2020. The entirety of the above-mentioned patent application is hereby incorporated by reference herein.

### TECHNICAL FIELD

The technical field relates to a bipolar transistor, especially a heterojunction bipolar transistor (HBT).

### BACKGROUND

Wireless communication devices require power amplifiers (PA) with high efficiency, superior RF performance, high linearity and high ruggedness. In the current mobile communication, the operating frequency of the PA has reached near high frequency or in the high frequency range. In the fifth-generation mobile communication, the operating frequency of the PA will even operate in a higher frequency range, such as sub-6 GHz or millimeter wave frequency bands. Hence, the efficiency, RF performance, linearity and ruggedness of the PA need to be further improved to achieve the proper operational performance or even optimize the operational performance in the high frequency or millimeter wave frequency bands.

The efficiency of a PA can be effectively improved by increasing the operating voltage or operating current. For example, the operating voltage or current of a PA can be higher through circuit design. In addition, the efficiency of a PA can also be improved by adjust the structure and/or material of the epitaxial layer of a heterojunction bipolar transistor (HBT).

However, when the HBT operates at a high voltage or a high current, the HBT is prone to damage due to excessive power. For example, when the PA and the antenna are not impedance matched, the excessive power bounced back will deteriorate the ruggedness of the HBT and the PA. Therefore, it is an important topic that the ruggedness of an HBT must be effectively improved under high voltage or high current (i.e., high power density) operation.

Please refer to US Patent Publication No. 2018/0240899 A1, “HETEROJUNCTION BIPOLAR TRANSISTOR,” which is referred to as Umemoto “899” hereinafter.

Umemoto “899” discloses that when the Kirk effect occurs, the quasi-electric field strength generated by the bandgap graded layer can increase the velocity of electrons in the base-collector junction so as to shorten the time for electrons to pass through the base-collector junction and reduce the decline in the output power of the HBT when the Kirk effect occurs.

### SUMMARY

According to Umemoto “899”, when the strength of the effective electric field falls within the range of about 0.5 or more times to about 2 or less times (i.e., from about 0.5 times to about 2 times) the peak electric field strength, an electron velocity equal to or higher than about 70% of the peak value is achieved. When the strength of the effective electric field falls within the range of about 0.7 or more times to about 1.5 or less times (i.e., from about 0.7 times to about 1.5 times) the peak electric field strength, an electron velocity equal to or higher than about 90% of the peak value is achieved. However, the maximum electron velocity is limited to about 90% of the peak velocity, and the performance of HBT based on Umemote “899” also has its limitation. In this way, the efficiency, RF performance, linearity and ruggedness of the HBT based on Umemote “899” is able to meet the requirement for the general wireless communication devices. However, based on Umemote “899,” the HBTs of the wireless communication devices may not operate normally in higher frequency ranges, such as sub-6 GHz or millimeter wave frequency bands.

The problems to be solved in the present disclosure are as follows: in the first aspect, the maximum velocity of electrons passing through the base-collector junction in Umemoto “899” is limited to 90% of the peak velocity as well as the knee voltage cannot be lowered. Specifically, after the peak velocity appears, the velocity of electrons will start to drop to 70% of the peak velocity or less than 90% of the peak velocity, and the efficiency and RF performance of the HBT cannot be further enhanced; in the second aspect, the ruggedness or linearity is difficult to improve or is difficult to significantly improve.

Third, in Umemoto “899”, when the bandgap graded layer is made of AlₓGa₁₋ₓAs and x>0.075, the cutoff frequency f_{T} of the HBT starts to decrease and the knee voltage of the HBT can no longer be reduced due to the current blocking effect. Therefore, it is necessary to reduce the influence of the collector current blocking effect to solve the problem that the total aluminum composition of the bandgap graded layer or the maximum aluminum composition of a certain part of the bandgap graded layer cannot be further increased, or the bandgap variation range of the bandgap graded layer cannot be further expanded. These problems will cause the knee voltage to not be further reduced, and will also make it difficult to improve the efficiency, RF performance, ruggedness or linearity of the HBT.

In one embodiment of the present disclosure, the HBT includes a collector layer. The collector layer includes a bandgap graded layer. The bandgap graded layer is formed in a part of or the entire of the collector layer.

The bandgap graded layer is used to generate a varying quasi-electric electric field strength, thereby accelerating the electrons passing through the bandgap graded layer. When the bandgap graded layer includes a semiconductor material in which an electron velocity does not peak at a certain electric field strength when an electric field strength is varied, and the strength of the quasi-electric field is at least 0.1 kV/cm or more.

When the bandgap graded layer includes a semiconductor material in which an electron velocity peaks at a certain electric field strength when an electric field strength is varied, and the strength of the quasi-electric field in a part of the bandgap graded layer greater than 1.8 or 2 times the peak electric field strength.

Umemoto “899” teaches that when the maximum quasi-electric field strength is reduced from 1.8 to 1.3 times the peak electric field strength, the electron velocity passing through the base-collector junction can be increased to 90% of the peak velocity form 70% of the peak velocity. The peak velocity is an electron velocity that peaks at a certain electric field strength when the electric field strength is varied. Umemoto “899” fails to teach that when the strength of the quasi-electric field is more than 1.8 times the peak electric field strength, the velocity of some electrons can be close to the peak velocity or exceed the peak velocity. The electron velocity passing through the base-collector junction can be close to the peak velocity or maintain at the peak velocity or reach the velocity overshot. When an electron is under a stronger quasi-electric field strength, and the electrons can gain energy within the energy relaxation time of the electrons, the velocity of the electrons can be accelerated by the stronger quasi-electric field strength, wherein when the quasi-electric field exceeds 1.8 times the peak electric field strength, the decline in electron velocity will be decreased. As a result, an electron velocity will be close to or reach the peak velocity or will even reach a velocity overshot. In principle, with the increase of the electric field, an electron velocity will be faster. Consequently, when the strength of the quasi-electric field in a part of the bandgap graded layer considerably exceeds the peak electric field strength, the overall velocity (average velocity) of the electrons in the bandgap graded layer can be faster than that of Umemoto “899”.

Compared with the prior art, the strength of the quasi-electric field of the bandgap graded layer in each embodiment of the present disclosure has a stronger electric field strength, so the velocity of some electrons is faster. In this way, the time for electrons to pass through the bandgap graded layer or the base-collector junction is shorten. Consequently, the RF performance or the output power of the HBT can be enhanced.

Since the electrons in the bandgap graded layer can gain energy from the quasi-electric field strength which is greater than 0.1 kV/cm or 1.8 times the peak electric field strength. As the time for electrons to pass through the bandgap graded layer or the base-collector junction is shorten, the collector current density Jc of the Kirk effect in the HBT will increase. The time for electrons to pass through the base-collector junction can also be shortened, thereby lowering the knee voltage of the HBT at high currents and improving the efficiency, output power or RF performance of the HBT.

Moreover, the RF performance of the HBT is related to the collector transient time (τ_{c}). It is well known that the shorter the τ_{c} is, the better the high-performance of the HBT is. In general, the common method to shorten τ_{c} is to reduce the thickness of the collector layer and/or increase the electron velocity, but the thinning of the collector layer usually causes the breakdown voltage to be lower. Once the breakdown voltage becomes lower, the output power of the power amplifier (PA) is easily limited.

In one embodiment, a wide bandgap layer is further provided in the bandgap graded layer. The bandgap graded layer with the wide bandgap layer cannot only help reduce the thickness of the collector layer but also maintain a proper breakdown voltage. Since the thickness of the collector layer can be reduced and the electrons can be accelerated, the time for electrons to pass through the collector layer can be further shortened such that the RF performance or efficiency of the HBT can be further improved.

Since the efficiency, RF performance, linearity or ruggedness of the HBT has been significantly improved, the performance of the PA can be enhanced when the HBT is applied to the PA of existing wireless communication devices. It is worth emphasizing that the HBT is also suitable for working at higher operating frequencies, such as operating in the frequency range below 6 GHz, below 10 GHz or even millimeter wave.

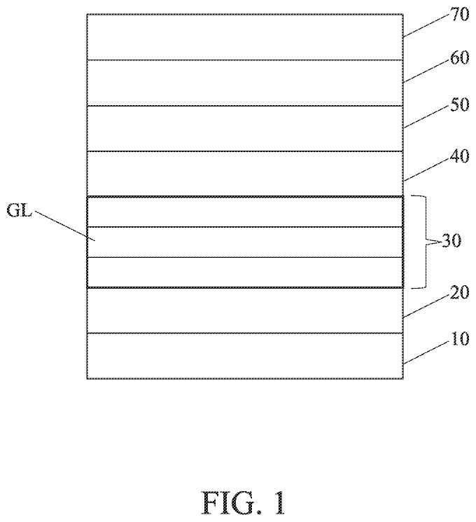

FIG. 1 is a schematic diagram of the bandgap graded layer according to one embodiment of the present disclosure.

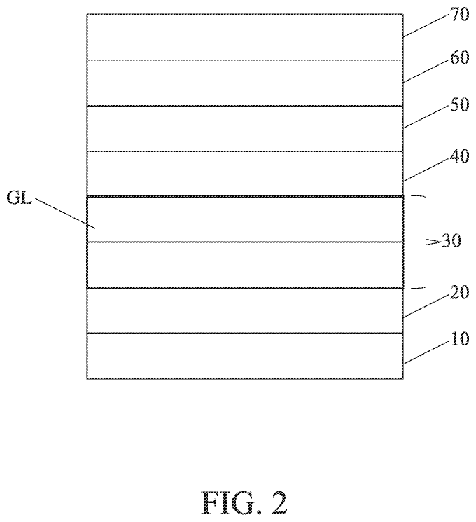

FIG. 2 is a schematic diagram of the bandgap graded layer according to another embodiment of the present disclosure.

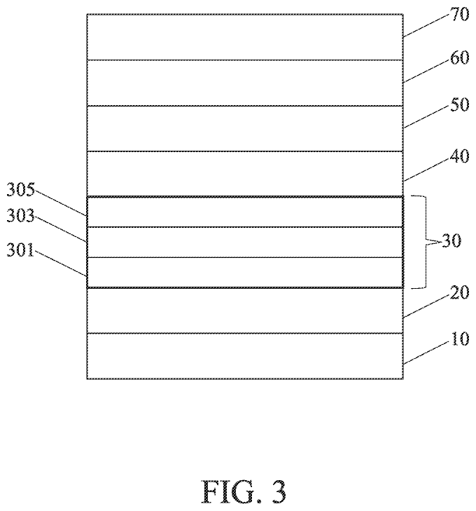

FIG. 3 is a schematic diagram of the bandgap graded layer according to an alternative embodiment of the present disclosure.

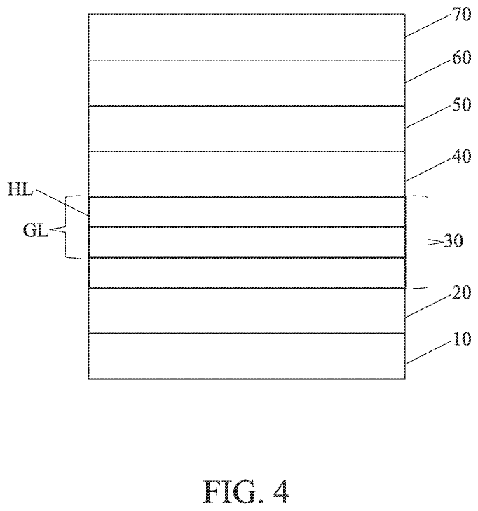

FIG. 4 is a schematic diagram of the hole blocking layer according to one embodiment of the present disclosure.

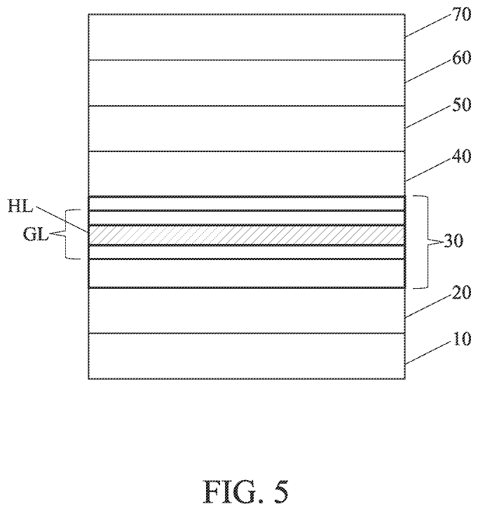

FIG. 5 is a schematic diagram of the hole blocking layer according to another embodiment of the present disclosure.

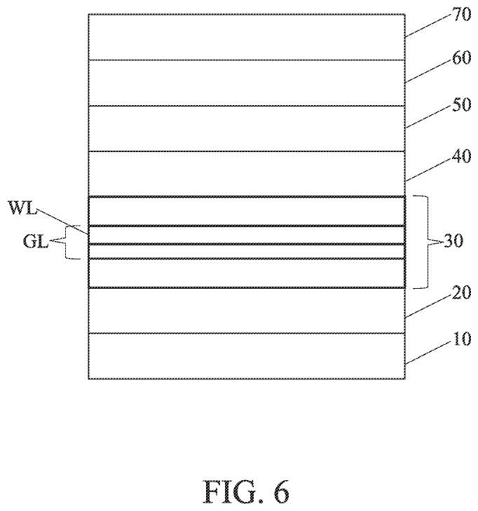

FIG. 6 is a schematic diagram of the wide bandgap layer according to one embodiment of the present disclosure.

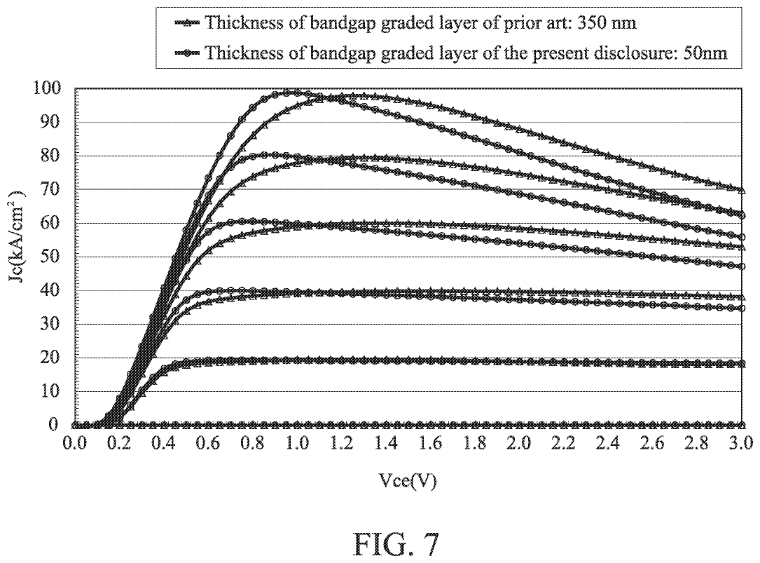

FIG. 7 is a comparison diagram showing the common emitter I-V characteristics of the collector layer of the HBT of the present disclosure and the common emitter I-V characteristics of the prior art HBT (please refer to Umemoto “899”).

### DESCRIPTION OF THE EMBODIMENTS

The embodiment of the present disclosure is described in detail below with reference to the drawings and element symbols, such that persons skilled in the art is able to implement the present application after understanding the specification of the present disclosure.

Specific examples of components and arrangements are described below to simplify the present disclosure. These are, of course, merely examples and they are not intended to limit the scope of the present disclosure. In the present disclosure, for example, when a first epitaxial layer formed above or on a second epitaxial layer, it may include an exemplary embodiment in which the first epitaxial layer is in direct contact with the second epitaxial layer, or it may include an exemplary embodiment in which other elements or epitaxial layers are formed between thereof, such that the first epitaxial layer is not in direct contact with the second epitaxial layer. In addition, repeated reference numerals and/or notations may be used in different embodiments, these repetitions are only used to describe some embodiments simply and clearly, and do not represent a specific relationship between the different embodiments and/or structures discussed.

Further, spatially relative terms, such as “underlying,” “below,” “lower,” “overlying,” “above,” “upper” and the like, may be used herein for ease of description to describe one element or feature's relationship to another element(s) or feature(s) as illustrated in the figures and/or drawings. The spatially relative terms are intended to encompass different orientations of the device in use or operation in addition to the orientation depicted in the figures and/or drawings. Moreover, certain terminology has been used to describe embodiments of the present disclosure. For example, the terms “one embodiment,” “an embodiment,” and “some embodiments” mean that a particular feature, structure or characteristic described in connection with the embodiment is included in at least one embodiment of the present disclosure. Therefore, it is emphasized and should be appreciated that two or more references to “an embodiment” or “one embodiment” or “an alternative embodiment” in various portions of the present disclosure are not necessarily all referring to the same embodiment.

Furthermore, the particular features, structures or characteristics may be combined in any suitable manner in one or more embodiments of the present disclosure. Further, for the terms “including”, “having”, “with”, “wherein” or the foregoing transformations used herein, these terms are similar to the term “comprising” to include corresponding features. In addition, a “layer” may be a single layer or a plurality of layers; and “a portion” of an epitaxial layer may be one layer of the epitaxial layer or a plurality of adjacent layers.

### First Embodiment

Referring to FIG. 1, the heterojunction bipolar transistor (HBT) includes a substrate 10, a sub-collector layer 20, a n-type collector layer 30, a p-type base layer 40, an n-type emitter layer 50, an emitter cap layer 60 and an ohmic contact layer 70. The n-type sub-collector layer 20, the n-type collector layer 30, the p-type base layer 40, the n-type emitter layer 50, the emitter cap layer 60 and the ohmic contact layer 70 are sequentially formed above the substrate 10. The doping concentration of the collector layer 30 is lower than the doping concentration of the sub-collector layer 20.

The collector layer 30 includes a bandgap graded layer GL, and the bandgap graded layer GL is formed in a part of or the entire of the collector layer 30. For example, the bandgap graded layer GL is at least one layer of the collector layer 30.

The bandgap graded layer may include a material selected from the group consisting of GaAs, AlGaAs, GaAsSb, GaAsPSb, InGaAs, InGaAsN, AlGaAsP, AlGaAsN, AlGaAsSb, AlGaAsBi, InGaP, InGaPN, InGaPSb, InGaPBi, InGaAsP, InGaAsPN, InGaAsPSb, InGaAsPBi, InAlGaP, InAlGaPN, InAlGaPSb and InAlGaPBi or other suitable materials. The material of the collector layer 30 includes a material selected from the group consisting of GaAs, InGaP, InGaAsP, InAlGaP and AlGaAs. The material of the base layer 40 includes a material selected from the group consisting of p-type GaAs, GaAsSb, GaAsPSb, InGaAs and InGaAsN.

The bandgap graded layer GL will generate a quasi-electric field. Strength of the quasi-electric field is an electric field generated by gradually grading the bandgap of the bandgap graded layer, which acts on electrons, so that the electrons can gain energy in the quasi-electric field and vary the velocity.

The strength of the quasi-electric field of the bandgap graded layer in the first embodiment is greater than 0.1 kV/cm; preferably, the strength of the quasi-electric field of the bandgap graded layer in the first embodiment is even greater than 0.2, 0.3, 0.5, 1, 2, 3, 4, 5, 6, 7, 8, 9, 10, 20, 30, 40, 50, 60, 70, 80, 90 or 100 kV/cm. In principle, the strength of the quasi-electric field of the bandgap graded layer in the first embodiment is about 0.1-100 kV/cm.

In principle, when the semiconductor material, thickness, composition or bandgap variation of the bandgap graded layer are adjusted or varied, the strength of the electric field will also be different.

### Second Embodiment

Umemoto “899” teaches that the bandgap graded collector layer contains a semiconductor material in which an electron velocity peaks at a certain electric field strength when an electric field strength is varied. Umemoto “899” further discloses that when the semiconductor material is AlGaAs in which the electron velocity peaks at a certain electric field strength when the electric field strength is varied. The electric field strength at which the electron velocity peaks is hereinafter referred to as “peak electric field strength” (referring to FIGS. 5A and 5B of Umemoto “899”). Regarding the definition of the quasi-electric field (strength) and peak electric field strength herein are the same as those of Umemoto “899”. Further, Umemoto “899” also mentioned the effective electric fields and the external electric fields. Please refer to Umemoto “899” for the definitions of the effective electric fields and external electric fields.

The main difference between the second embodiment and the first embodiment is that the bandgap graded layer of the second embodiment includes a semiconductor material in which the electron velocity “peaks” at a certain electric field strength when the an electric field strength is varied, while the bandgap graded layer of the first embodiment includes a semiconductor material in which the electron velocity “does not” peak at a certain electric field strength when the electric field strength of the bandgap graded layer is varied. In addition, certain semiconductor materials, such as AlGaAs, may generate obvious peak electric field strength or may not generate (obvious) peak electric field strength through the ratio of material composition. For other aspects, such as the structure of each epitaxial layer and the materials of the epitaxial layers, please refer to the first embodiment or make appropriate selections according to actual needs.

The strength of the quasi-electric field of the bandgap graded layer in the second embodiment is greater than 1.8, 1.9, 2.0, 2.1, 2.2, 2.3, 2.4, 2.5, 2.6, 2.7, 2.8, 2.9, 3.0, 3.1, 3.5, 4.0, 4.5, 5.0 or 5.5 times the peak electric field strength. In some embodiments, at least a portion of the bandgap graded layer is the semiconductor material that generates the strength of the quasi-electric field which is greater than 1.8 times the peak electric field strength. The material of the bandgap graded layer of the second embodiment includes AlGaAs, GaAsSb, InGaAs, InGaAsN, InAlAs, InAlGaAs, or a suitable combination of the foregoing materials.

For example, if the semiconductor material of the bandgap graded layer is AlₓGa₁₋ₓAs in which the value of x is between 0 and 0.1 (specifically, if the aluminum composition in the bandgap graded layer varies from 0 to 0.11, and the thickness of the bandgap graded layer does not exceed 300 nm), the strength of the quasi-electric field of the bandgap graded layer of the second embodiment can be greater than 6120 V/cm. Preferably, the thickness of the bandgap graded layer may be between 20 nm and 300 nm. For example, the thickness of the bandgap graded layer may be 250 nm, 100 nm, 150 nm or 50 nm. In principle, when the thickness of the bandgap graded layer is thinner, the strength of the quasi-electric field of the bandgap graded layer will be greater. However, the strength of the quasi-electric field of the bandgap graded layer will also vary with the material composition ratio of AlₓGa₁₋ₓAs or th variation range of aluminum composition. Preferably, the strength of the quasi-electric field of the bandgap graded layer may be even greater than 6460, 6800, 7140, 7480, 7820, 8160, 8500, 8840, 9180, 9520, 9860, 10200, 10540, 11900, 13600, 15300, 17000 or 18700 V/cm. In principle, the strength of the quasi-electric field of the bandgap graded layer is between 6120 V/cm and 18700 V/cm.

In addition, in the first and second embodiments, the bandgap graded layer generates a quasi-electric field strength, wherein it may be sufficient to generate the required electric field strength in a section of the quasi-electric field (such as one or several layers of the bandgap graded layer). In the first and second embodiments, when the electric field strength of a section of the quasi-electric field strength is strong, the electron velocity decreases less, or maintains at the peak velocity, or reaches the velocity overshot.

In the bandgap graded layers of the first and second embodiments, the bandgap variation includes the first bandgap variation in which a bandgap varies to narrow with increasing a distance from the base layer. Additionally, the bandgap variation may further include a “second bandgap variation” in which a bandgap varies to widen with increasing a distance from the base layer, a “third bandgap variation” in which a bandgap of the bandgap graded layer is constant, or both. The sequence of the “second bandgap variation” and the “third bandgap variation” is not restricted, and depends on actual needs. Besides, in the third bandgap variation, the bandgap of the bandgap graded layer will be between the bandgaps of two semiconductor layers adjacent to the bandgap graded layer. By means of the “second bandgap variation” and the “third bandgap variation,” the discontinuity of the conduction band between the bandgap graded layer and the base layer can be smaller, the collector current blocking effect can be reduced or eliminated, and the hole barrier can be higher.

In terms of the first bandgap variation, when the bandgap graded layer in the collector layer is close to the base layer (referring to FIG. 2), the maximum bandgap of the bandgap graded layer can be approximately at its junction close to the base layer, but is not limited thereto. Alternatively, when the collector layer 30 includes a bottom layer 301, a middle layer 303 and a top layer 305 (referring to FIG. 3), and if the bandgap graded layer is the middle layer 303 and the bandgap graded layer is the first bandgap variation, the minimum bandgap of the bandgap graded layer may be approximately at or near its junction close to the bottom layer 301, but is not limited thereto.

In one embodiment, if the bandgap graded layer is the top layer 305 and the bandgap graded layer is the second bandgap variation, the minimum bandgap of the bandgap graded layer may be approximately at or near its junction close to the base layer, but is not limited thereto. The bandgap of the base layer at the junction of the bandgap graded layer and the base layer may be approximately the same as the minimum bandgap of the bandgap graded layer, but is not limited thereto. In another embodiment, if the bandgap graded layer is the middle layer and the bandgap graded layer is the second bandgap variation, the maximum bandgap of the bandgap graded layer is at or near its junction close to the bottom layer.

Moreover, the bandgap variation of the first bandgap variation or the second bandgap variation may be a linear bandgap gradation, a non-linear bandgap gradation, a stepped bandgap gradation or any combination of the forgoing.

### Third Embodiment

Referring to FIG. 4, a part of the bandgap graded layer GL is further provided with a hole blocking layer HL. A part of the bandgap or maximum bandgap of the hole blocking layer HL needs to be greater than the bandgap of the base layer to increase the hole barrier and block the holes such that the offset voltage and knee voltage of the HBT can be reduced, thereby improving the performance of the HBT or power amplifier (PA). In one embodiment, referring to FIG. 5, the hole blocking layer HL is disposed in the middle layer of the bandgap graded layer (the middle layer 301 in FIG. 3). The semiconductor layer beneath the hole blocking layer HL (the bottom layer 301 in FIG. 3) may have the first bandgap variation. The semiconductor layer on the hole blocking layer HL (the top layer in FIG. 3) may have the second bandgap variation and/or the third bandgap variation.

The hole blocking layer HL includes at least one material selected from the group consisting of GaAsPSb, GaAs, GaAsSb, InGaP, InGaAsP, InGaAs, InGaAsN, AlₓGa₁₋ₓAs, AlₓGa₁₋ₓAs_{1-y}N_{y}, AlₓGa₁₋ₓAs_{1-z}P_{z}, AlₓGa₁₋ₓAs_{1-w}Sb_{w} and InᵣAlₓGa₁₋ₓ₋ᵣAs, wherein the value of x is 0<x<1; or a maximum value of x is 0.03≤x≤0.8; or a maximum value of x is 0.05≤x≤0.22, and y, z, r and w≤0.1.

Since the bandgap (or maximum bandgap) of the hole blocking layer HL is greater than the bandgap of the base layer, the saturation current of the base-collection junction will be reduced, and the diffusion capacitance of the base-collector junction of the HBT will also be reduced. When the base-collector junction voltage varies, the variation in the diffusion capacitance of the base-collector junction becomes smaller such that the cutoff frequency f_{T} of the HBT will be increased (when it is close to the saturation region or when it works in the saturation region). In addition, the range of the cutoff frequency f_{T} becomes smaller with the variation of the collector current such that the linearity of the HBT will also be improved.

Therefore, a hole barrier can be formed at the junction of the hole blocking layer and the base layer, or a hole quantum well can be formed at the junction of the hole blocking layer and the collector layer. Under excessively high power operation, the hole barrier at the junction of the hole blocking layer and the base layer can block a sufficient amount of holes to cause the blocking effect, or alternatively the hole quantum well at the junction of the hole blocking layer and the collector layer will accumulate enough holes to cause deterioration of the RF performance and limit excess output power. As a result, damage to the HBT due to excessively high operating power is avoided, and the ruggedness of the HBT can be improved.

Based on the aforementioned embodiments, in the short time after some electrons in the bandgap graded layer reach the peak velocity, the decline of the electron velocity can be reduced, can be close to or around the peak velocity, or can exceed the peak velocity such that the threshold for the HBT to reach the collector current density of Kirk effect will increase. Since the time for electrons to pass through the base-collector junction can be significantly shortened, the knee voltage of the HBT can also be reduced, and the efficiency, linearity, output power or RF performance of the HBT can be improved.

In the second embodiment, when the strength of the quasi-electric field exceeds 1.8 times the peak electric field strength, the electron velocity in the bandgap graded layer will be close to the peak velocity, or the electron velocity in the bandgap graded layer will maintain at the peak velocity, or the electron velocity in the bandgap graded layer will reach the velocity overshot. As a result, the influence caused by the collector current blocking effect will be relatively slight such that the aluminum composition can be moderately higher, or the bandgap variation can be moderately increased. When the aluminum composition is increased, or the bandgap variation is increased, the cutoff frequency f_{T} can be higher, and the knee voltage can be lower. Therefore, it helps to improve the RF performance, output power or ruggedness of the HBT.

In one embodiment, a wide bandgap layer WL is further provided in the bandgap graded layer GL, wherein the wide bandgap layer may be formed in the first bandgap variation, the second bandgap variation and/or the third bandgap variation. The configuration of the wide bandgap layer WL makes the hole barrier higher, thereby improving the blocking effect on the holes. As such, it helps to reduce the knee voltage and also helps to improve the efficiency of the HBT. The wide bandgap layer includes a material selected from the group consisting of AlGaAs, AlGaAsP, AlGaAsN, AlGaAsSb, AlGaAsBi, InGaP, InGaPN, InGaPSb, InGaPBi, InGaAsP, InGaAsPN, InGaAsPSb, InGaAsPBi, InAlGaP, InAlGaPN, InAlGaPSb, InAlGaPBi, or the combination of the foregoing, wherein the bandgap of InGaP is greater than 1.86 eV, 1.87 eV, 1.88 eV, 1.89 eV, 1.90 eV or 1.91 eV. Preferably, the thickness of the wide bandgap layer is less than or equal to 15 nm but not does not include 0.

According to the embodiments of the present disclosure, when the strength of the quasi-electric field exceeds 1.8 times the peak electric field strength, electrons can pass through the bandgap graded layer or the collector-base junction in a shorter time, which helps to significantly improve the efficiency, RF performance, linearity or ruggedness of the HBT.

In some embodiments, a spacer (not shown) is further included. The spacer is formed between the bandgap graded layer and the base layer and/or formed between the bandgap graded layer and the “collector layer beneath the bandgap graded layer.” The spacer mainly includes a III-V semiconductor material, for example, the material of the spacer is GaAs, GaAsSb, GaAsPSb, InGaAs, InGaAsN, AlGaAs, AlGaAsSb, AlGaAsP, InAlGaAs, AlGaAsN or a combination of above materials. It is worth mentioning that the spacer can be p-type doped (the doping concentration is less than 1×10¹⁹/cm³, the preferred doping concentration is less than 1×10¹⁸/cm³, and the more preferred doping concentration is less than 1×10¹⁷/cm³), undoped or n-type doped. The preferred spacer can be undoped or n-type doped. The more preferred spacer can be n-type doped with a doping concentration greater than 1×10¹⁵/cm³. The preferred doping concentration is between 1×10¹⁵/cm³ and 1×10¹⁹/cm³, and the more preferred doping concentration is between 1×10¹⁶/cm³ and 5×10¹⁸/cm³. It is worth mentioning that the thickness of the spacer can be between 0.1 nm and 100 nm; the preferred thickness of the spacer can be between 3 nm and 80 nm; and the more preferred thickness of the spacer can be between 5 nm and 50 nm.

In some embodiments, an intermediate composite layer (not shown) is further included. The intermediate composite layer is located between the substrate 10 and the sub-collector layer 20. The intermediate composite layer includes a buffer layer. The buffer layer is mainly composed of a III-V semiconductor material. Alternatively, the intermediate composite layer may include a field effect transistor.

Alternatively, the intermediate composite layer may include a pseudomorphic high electron mobility transistor (which is sequentially stacked on the substrate) including: at least one buffer layer, a first donor layer, a first spacer layer, a channel layer, a second spacer layer, a second donor layer, a Schottky layer, an etch stop layer and a cap layer for ohmic contact (not shown). The material of the buffer layer is selected from a III-V semiconductor material. The material of the first donor layer or the second donor layer is selected from the group consisting of n-type semiconductor materials of GaAs, AlGaAs, InAlGaP, InGaP and InGaAsP. The material of the first spacer layer or the second spacer layer is selected from the group consisting of semiconductor materials of GaAs, AlGaAs, InAlGaP, InGaP and InGaAsP. The material of the channel layer is selected from the group consisting of semiconductor materials of GaAs, InGaAs, AlGaAs, InAlGaP, InGaP and InGaAsP. The material of the Schottky layer is selected from the group consisting of semiconductor materials of GaAs, AlGaAs, InAlGaP, InGaP and InGaAsP. The material of the etch stop layer is selected from the group consisting of semiconductor materials of GaAs, AlGaAs, InAlGaP, InGaAsP, InGaP and AlAs. The material of the cap layer is selected from a n-type III-V semiconductor material.

FIG. 7 is a comparison diagram showing the common emitter I-V characteristics of the HBT in the embodiment of FIG. 3 and the common emitter I-V characteristics of the prior art HBT (i.e., Umemoto “899”). The structure of the prior art HBT is roughly the same as that shown in FIG. 3 of the present disclosure. That is, the total thickness of the collector layer in the embodiment of FIG. 3 and the prior art HBT (hereinafter referred to as both) is 1100 nm, but the thicknesses of the bandgap graded layers (middle layer) of both are different. The thickness of the bandgap graded layer in FIG. 3 is 50 nm, while the thickness of the bandgap graded layer of the prior art HBT is 350 nm.

The top layers of both are made of AlₓGaAs, the thickness thereof is 20 nm, the n-type doping concentration thereof is 1×10¹⁵/cm³, and x gradually rises from 0 to 0.11 (that is, the second bandgap variation: a bandgap varies to widen with increasing a distance from the base layer). The bandgap graded layers of both are made of n-type AlₓGaAs, the n-type doping concentration thereof is 1×10¹⁵/cm³, and x decreases from 0.11 to 0 (that is, the first bandgap variation: a bandgap varies to narrow with increasing a distance from the base layer). The bottom layers of both are made of GaAs, and the n-type doping concentration thereof is 1×10¹⁶/cm³.

The first bandgap variation and the second bandgap variation are approximately linear variations.

According to the aforementioned conditions, it can be known that the strength of the quasi-electric field generated by the bandgap graded layer of the embodiment of FIG. 3 is about 5 to 6 times the peak electric field strength, while the strength of the quasi-electric field generated by the prior art HBT is about 1 times the peak electric field strength. It can be seen from the common emitter I-V characteristics of FIG. 7 that the knee voltage of the embodiment of FIG. 3 is indeed significantly lower. This is because electrons can pass through the bandgap graded layer or base-collector junction at a faster velocity such that the collector current density Jc where the Kirk effect occurs in the HBT of FIG. 3 will increase. Consequently, the knee voltage of the HBT of FIG. 3 can be reduced under high current density, and the efficiency, output power or high-frequency performance of the HBT can be improved.

The features of several embodiments are summarized above such that persons skilled in the art can better under the aspects of the present disclosure. Persons skilled in the art should understand that persons skilled in the art can easily use the present disclosure as a basis for designing or modifying other processes and structures. These other processes and structures are used to perform the same purpose of the embodiments introduced herein and/or achieve the same advantages of the embodiments. Persons skilled in the art should also understand that the equivalent structures do not depart from the spirit and scope of the present disclosure. Persons skilled in the art can make various changes, substitutions or alterations without departing from the spirit and scope of the present disclosure.

What is claimed is:

1. A heterojunction bipolar transistor, comprising:
a substrate;
a collector layer;
a base layer; and
an emitter layer,
wherein at least the collector layer, the base layer and the emitter layer are formed above the substrate,
wherein the collector layer comprises a bandgap graded layer with a bandgap variation, and the bandgap variation comprises at least one first bandgap variation in which a bandgap varies to narrow with increasing a distance from the base layer,
wherein the bandgap graded layer generates a quasi-electric field, and strength of the quasi-electric field is an electric field that acts on electrons as a result of the bandgap variation of the bandgap graded layer,
wherein the bandgap graded layer comprises a semiconductor material in which an electron velocity does not peak at a certain electric field strength when an electric field strength is varied, and
wherein the strength of the quasi-electric field is greater than 0.1 kV/cm.

2. The heterojunction bipolar transistor as claimed in claim 1, wherein the strength of the quasi-electric field is greater than 0.2 kV/cm.

3. The heterojunction bipolar transistor as claimed in claim 1, wherein the bandgap graded layer comprises a material selected from the group consisting of GaAs, AlGaAs, GaAsSb, GaAsPSb, InGaAs, InGaAsN, AlGaAsP, AlGaAsN, AlGaAsSb, AlGaAsBi, InGaP, InGaPN, InGaPSb, InGaPBi, InGaAsP, InGaAsPN, InGaAsPSb, InGaAsPBi, InAlGaP, InAlGaPN, InAlGaPSb and InAlGaPBi.

4. The heterojunction bipolar transistor as claimed in claim 1, wherein the bandgap variation further comprises a second bandgap variation in which a bandgap varies to widen with increasing a distance from the base layer or a third bandgap variation in which a bandgap of the bandgap graded layer is constant.

5. A heterojunction bipolar transistor, comprising:
a substrate;
a collector layer;
a base layer; and
an emitter layer,
wherein at least the collector layer, the base layer and the emitter layer are formed above the substrate
wherein the collector layer comprises a bandgap graded layer with a bandgap variation, and the bandgap variation comprises at least one first bandgap variation in which a bandgap varies to narrow with increasing a distance from the base layer,
wherein the bandgap graded layer generates a quasi-electric field, and strength of the quasi-electric field is an electric field that acts on electrons as a result of the bandgap variation of the bandgap graded layer,
wherein the bandgap graded layer comprises a semiconductor material in which an electron velocity does not peak at a certain quasi-electric field strength when an quasi-electric field strength is varied, and wherein the strength of the quasi-electric field is more than 1.8 times the peak electric field strength but not including 1.8 times the peak electric field strength.

6. The heterojunction bipolar transistor as claimed in claim 5, wherein the semiconductor material comprises a material selected from the group consisting of AlGaAs, GaAsSb, InGaAs, InGaAsN, InAlGaAs, and InAlAs.

7. The heterojunction bipolar transistor as claimed in claim 5, wherein the strength of the quasi-electric field is greater than 6120 V/cm.

8. The heterojunction bipolar transistor as claimed in claim 5, wherein the strength of the quasi-electric field is greater than 6460 V/cm.

9. The heterojunction bipolar transistor as claimed in claim 5, wherein the bandgap variation further comprises a second bandgap variation in which a bandgap varies to widen with increasing a distance from the base layer or a third bandgap variation in which a bandgap of the bandgap graded layer is constant.

10. The heterojunction bipolar transistor as claimed in claim 5, wherein the bandgap graded layer further comprises a hole blocking layer, wherein a bandgap of the hole blocking layer is greater than a bandgap of the base layer.

11. The heterojunction bipolar transistor as claimed in claim 10, wherein the hole blocking layer comprises a material selected from the group consisting of GaAsPSb, GaAs, GaAsSb, InGaP, InGaAsP, InGaAs, InGaAsN, AlₓGa₁₋ₓAs, AlₓGa₁₋ₓAs_{1-y}N_{y}, AlₓGa₁₋ₓAs_{1-z}P_{z}, AlₓGa₁₋ₓAs_{1-w}Sb_{w} and InᵣAlₓGa₁₋ₓ₋ᵣAs, and wherein a value of x is 0<x<1; or a maximum value of x is 0.03≤x≤0.8; or a maximum value of x is 0.05≤x≤0.22, and y, z, r and w≤0.1.

12. The heterojunction bipolar transistor as claimed in claim 5, wherein the bandgap graded layer further comprises a wide bandgap layer, and the wide bandgap layer comprises a material selected from the group consisting of AlGaAs, AlGaAsP, AlGaAsN, AlGaAsSb, AlGaAsBi, InGaP, InGaPN, InGaPSb, InGaPBi, InGaAsP, InGaAsPN, InGaAsPSb, InGaAsPBi, InAlGaP, InAlGaPN, InAlGaPSb and InAlGaPBi.

13. The heterojunction bipolar transistor as claimed in claim 9, wherein the bandgap graded layer further comprises a wide bandgap layer, and the wide bandgap layer is arranged in the first bandgap variation, the second bandgap variation or the third bandgap variation.

14. The heterojunction bipolar transistor as claimed in claim 12, wherein a bandgap of InGaP is greater than 1.86 eV.
